(19) United States
(12) Patent Application Publication
(10) Pub. No.: US 2015/0305092 A1
(43) Pub. Date: Oct. 22, 2015

(54) HEATER NANO DYE, SYSTEM INCLUDING SOLID HEATER NANO DYE LAYER, AND METHODS OF USING THE SAME

(71) Applicant: Vedat KAYNAK, Izmir (TR)

(72) Inventor: Vedat KAYNAK, Izmir (TR)

(21) Appl. No.: 14/476,333

(22) Filed: Sep. 3, 2014

(30) Foreign Application Priority Data
Apr. 18, 2014 (TR) 2014-G-141544

(51) Int. Cl. H05B 3/14; H05B 3/26; H01L 37/02; C09D 183/04

(52) U.S. Cl. CPC H05B 3/146; C09D 183/04; H05B 3/26; H01L 37/025

(57) ABSTRACT

An electrical system that includes a substrate having a surface, a solid heater nano dye layer disposed over the surface, and a power system having a positive terminal in electrical communication with a first position on the heater nano dye layer and a negative terminal in electrical communication with a second position on the heater nano dye layer is disclosed. The heater nano dye layer includes nanographite particles disposed within a continuous material. Also disclosed are methods of making the solid heater nano dye layer, as well as, methods of using the solid heater nano dye layer for heating and energy harvesting.

### CROSS-REFERENCE TO RELATED APPLICATION

This application claims priority to Turkish Application No. 2014-G-141544 filed Apr. 18, 2014, the entirety of which is incorporated herein by reference in its entirety.

### TECHNICAL FIELD

The innovation is associated with a heater nano dye that has been developed for the purpose of enabling resistance heating devices (e.g., ovens, water heater, gas heater, baking oven, boiler, radiation, infrared heaters, air conditioners, radiators, irons, central heating boilers, fan heaters, wall-to-wall and ceiling heating systems, heat pumps, LPG and automobile heaters, convectors, laundry and dish washing machine heaters, etc.) which are used in all fields of life and industry, as well as the liquid heating systems with solar energy and heating systems with solar battery, to reach same temperature values with less energy.

### Known Status of Technique

The heating systems that are operated with electric energy obtain heat generally with the aid of resistance (ohmic load). Although it has different types and applications, the resistance is generally made through wrapping or sizing the special chrome wires to the necessary ohms in circle and flat forms. These applications can be performed as allowed by the technique.

The resistance provides heat as proportional to the diameter and length of the wire and the power (w) changes according to this ratio. Since the metal wires expand when heated, they hang down and get elongated, and the probability of a break down as a result of a stroke or fall during these times is high.

In the known situation; in any place of the world, a toaster operates with the heat transfer as a result of attaching the resistance, even in different forms, to the metal pans. The water heater heats water by means of the heat transferred by the immersed resistance to the water in certain powers (w).

The convector operates through providing hot air to the environment as the air passing from there raises by means of placing the different forms of resistances within a body.

Different types of irons operate as a result of the electric energy heating of the chrome-nickel wires that are placed within dielectric ceramic dusts as not to contact with the body in the metal base and not to cause a short-circuit.

Radiation heaters operate by means of giving electromagnetic beams with the electric energy provided through the formation of the resistances formed of spiral wires located within a glass tube at certain ohms. Compared to the other heaters, the heaters that operate with the impact of beam give off radiation at high amounts and constitute danger for the health of human.

The electrical heaters also operate with resistance and they are manufactured in 2 types. While one type operates through the placement of a jacketed resistance in a tube and the heating of the water passing from here, the other type heats the water with the operation of the open resistance wire in the water. The open resistance type heaters constitute a very big danger and may cause electric shock related deaths in the places having no or insufficient grounding system.

In the laundry and dish washing machines, the heat is obtained as a result of the operation of the jacketed resistance within water at certain powers.

Electrical Central Heating Boilers heat the environment by means of obtaining hot water through the consumption of high amounts of energy by applying no. 1 immerse jacketed resistance in the mono-phase or no. 3 immerse jacketed resistance in three-phase according to the area to be heated and through transmitting this hot water from the radiators.

Heating with the energy obtained through the solar battery is ultimately costly. Since the heaters operating with the resistance logic need high power (w), it can be only possible to have these powers with an application like solar battery land and this is an expensive method. While the energy amount required for many white appliances at your home can be provided with solar battery, the process of heating with resistance is not applied commonly since it needs an onerous investment.

Since the metal resistances are the only technology used within the heating technology, no necessity has been required to make a research on the equivalents. Therefore, the heating methods have been applied within the possibilities provided by the metal resistances and no survey has been conducted concerning their losses. However, the loss of heat plays an important role for the efficiency of the system and causes the loss of energy. These losses of energy cause more electric consumption and more load compared to the electric energy provider systems. In this period where obtaining any kind of energy on the world getting harder and valuable, if we consider that even 1% saving is important, then the importance of these losses reveal in a clearer manner.

The heater Nano Dye described herein is designed to fulfill the heating process with low energy by means of applying different construction and building instead of the other heaters in the known situation of the technique.

One objective of the invention is to provide national contributions with the savings starting from 10% and reaching to 70%.

Another objective of the invention is; when the reverse operation of the system is performed; in other words, when the electric energy is provided, the Heater Nano Dye, from which the thermal energy is obtained, has the capability of generating electric when the thermal energy is transmitted.

Another objective of the invention is using the Heater Nano Dye to transform the solar energy or thermal energy into heat. With the aid of this capability, it is targeted to benefit from the sun or other heat sources in a more efficient manner with different constructions.

These and other features, objects and advantages of the present invention will become more apparent to one skilled in the art from the following description and claims when read in light of the accompanying drawings.

### BRIEF DESCRIPTION OF THE DRAWINGS

FIG. 1 is a schematic of an electrical system as described herein.

FIG. 2 is a cross-section of the heater nano dye layer-substrate composite of FIG. 1 take along cut line A-A.

FIG. 3 is a cross-section of the heater nano dye layer-substrate composite of FIG. 1 take along cut line A-A, with a dielectric material between the heater nano dye layer and the substrate.

FIG. 4, is a cross-section of the heater nano dye layer-substrate composite of FIG. 1 take along cut line A-A, with a dielectric layer and a thermally insulating material between the heater nano dye layer and the substrate.

### DETAILED DESCRIPTION OF INVENTION

The heater nano dye disclosed herein is provided in a liquid form. The liquid heater nano dye can be applied onto objects to form a solid layer once the reactants react and the volatile components evaporate or are heated off.

Ingredients of the heater nano dye can include nano graphite, polymethylphenylsiloxane, organic solvents (e.g., xylene, toluene, butylene glycol, acetone), carbon, alkyl acetate, aluminum, boron, pigments, and additional auxiliary ingredients. The heater nano dye layer can include the solid components of the heater nano dye solution, which include, but are not limited to, nano graphite, carbon, aluminum, boron, pigments, and solid auxiliary ingredients.

The nano graphite can have particles sizes ranging from 1 to 150 μm, or from 1.5 to 100 μm. In some embodiments, the nano graphite can be isotropic, while the nano graphite can be anisotropic in other embodiments. The nano graphite can be electrically conductive. The nano graphite can have a bulk density of less than 2 mg/m³, an electrical resistivity of less than 10 μΩ·m, or both. Examples of nano graphite useful in the heater nano dye include IG-43 isotropic, high-density graphite sold by Toyo Tanso Co., Ltd.

The nano carbon can have particles sizes ranging from 10 to 500 nm, or from 100 to 450 nm. Examples of carbon useful in the heater nano dye include amorphous carbon black sold by YontasYavuzlar Plastics (Turkey).

The aluminum can have particles sizes ranging from 10 to 500 μm, or 100 to 450 μm, or 180 to 400 μm. Examples of aluminum useful in the heater nano dye include aluminum dust sold by BMS METAL MADENCILIKIMALAT GERI DONUSUM SAN. Ve TIC. A.S. (Turkey).

The boron can be boron carbide having particle sizes ranging from 1 to 200 μm, or 5 to 100 μm, or 7 to 50 μm, or 10 to 30 μm, or any combination thereof. The boron can be the α-, β-, γ-, or τ-allotrope. In some embodiments, the boron comprises the β-phase. In some embodiments, the boron comprises at least 51 wt-% of the β-phase, or at least 70 wt-% of the β-phase, or at least 80 wt-% of the β-phase, or at least 90 wt-% of the β-phase. Examples of boron useful in the heater nano dye include boron carbide (F 400) sold by BoroptikMühendislikArgelmalatveTicaret Ltd. [symbol] ti. (Turkey)

The polymethylphenylsiloxane can have a viscosity of 13-24 mm²/s at 25° C. The polymethylphenylsiloxane can be a solution of approximately 50-53 wt-% polymethylphenylsiloxane resin in a xylene and/or toluene solvent. The maximum acid number can be no more than 1 mg KOH/g of solution. The polymethylphenylsiloxane gels or polymerizes at 200° C.±3° C. in a relatively short time (e.g., less than 60 minutes, or less than 30 minutes, or less than 15 minutes). Thus, when the final mixture is applied to a surface and cured, the polymethylphenylsiloxane can function as a binder holding the other components of the heater nano dye together. Examples of polymethylphenylsiloxanes useful as described herein include SILOEN® sold by ST KIMYASALMADDELER TIC. Ve SAN. LTD. STI. (Turkey).

The alkyl acetate can have a structure of CH₃(CH₂)ₙO(C═O)CH₃, where n=1 to 10. In some embodiments, the alkyl acetate is selected from the group consisting of ethyl acetate, propyl acetate (n- and iso-), butyl acetate (n-, iso-, tert-, and sec-), and pentyl acetate and hexyl acetate.

Examples of organic solvents include, but are not limited to, acetic acid, acetone, acetonitrile, 1- and 2-butanol, 2-butanone, t-butyl alcohol, carbon tetrachloride, chlorobenzene, chloroform, cyclohexane, 1,2-dichloroethane, propylene glycol, 1,2-butylene glycol, diethylene glycol, diethyl ether, diethylene glycol dimethyl ether, 1,2-dimethoxy ethane, dimethyl formanide, dimethyl sulfoxide, 1,4-dioxane, ethanol, ethyl acetate, ethylene glycol, glycerin, heptane, hexamethylphosphoramide, hexamethylphosphoroustriamide, hexane, methanol, methyl t-butyl ether, methylene chloride, N-methyl-2-pyrrolidone, nitromethane, pentane, petroleum ether, 1-propanol, 2-propanol, pyridine, tetrahydrofuran, toluene, triethyl amine, water, o-xylene, m-xylene, and p-xylene.

Table 1, below, provides examples of ranges of the heater nano dye components.

| | 1^{st} Range | 2^{nd} Range | 3^{rd} Range |
|---|---|---|---|
| nano-graphite | 15-40 wt-% | 3-50 wt-% | 1-45 wt-% |
| polymethylphenylsiloxane | 5-30 wt-% | 5-25 wt-% | 5-35 wt-% |
| alkylene glycol | 5-15 wt-% | 3-20 wt-% | 2-22 wt-% |
| organic solvents | 10-40 wt-% | 5-40 wt-% | 3-30 wt-% |
| xylene | 5-10 wt-% | 5-15 wt-% | 1-20 wt-% |
| toluene | 10-30 wt-% | 6-40 wt-% | 4-35 wt-% |
| acetone | 5-20 wt-% | 2-20 wt-% | 1-18 wt-% |
| alkyl acetate | 5-15 wt-% | 10-20 wt-% | 5-20 wt-% |
| Carbon | 10-50 wt-% | 15-60 wt-% | 20-65 wt-% |
| Boron | 2-30 wt-% | 5-45 wt-% | 2-45 wt-% |
| aluminum | 5-20 wt-% | 5-20 wt-% | 1-15 wt-% |
| special colorants | 15-50 wt-% | 5-40 wt-% | 5-40 wt-% |

Useful ranges of any particular ingredient in table 1 above, can also include any combination of the upper and lower ranges for that ingredient. For example, the range of nano graphite can range from 15 to 50 wt-%, or 3 to 45 wt-%, or 40-50 wt-%.

In some embodiments, all ingredients can be mixed together simultaneously. In other embodiments, the ingredients can be mixed into different components (e.g., a solid component and one or more liquid components, or at least two liquid components).

The heater nano dye is a liquid formed by mixing the heater nano dye ingredient at certain rates. While mixing, it is important to mix certain chemicals in a certain order and system. The nano graphite, carbon, and boron are mixed to form a solid component, which can be kept within a container (container no. 1). A first liquid component can include uniform mixture of butyl acetate, butylene glycol, and an organic solvent (e.g., toluene, acetone) in a second container (container no. 2).

A second liquid component can be obtained through mixing polymethylphenylsiloxane, aluminum, and an organic solvent (e.g., xylene and toluene) in a third container (container no. 3). After these mixtures are prepared separately and allowed to age for a certain time, the solid component (container no. 1) and the two liquid components (container nos. 2 & 3) are mixed in certain order and at certain amounts for a certain time.

In some embodiments, the mixture will include 10-80 wt-% first container ingredients, 10-40 wt-% second container ingredients, and 5-60 wt-% third container ingredients, where all percentages are based on the total weight of the mixture.

In some embodiments, the aging time for each container will independently be at least 10 minutes, or at least 20 minutes, or at least 30 minutes. In some embodiments, the aging time for each container will independently by 2 hours or less, or 1.5 hours or less, or 1 hour or less. For example, in some embodiments, the aging time of the first container can be 40-60 minutes, while the aging time of the second container can be 35-55 minutes, while the aging time of the third container can be 20-40 minutes.

This mixture obtained is allowed to react until a sufficient viscosity if produced, at which time the Heater Nano Dye is ready to apply to a surface. Generally, this is the time required for the solid components to become dispersed within the mixture and for the soluble components to dissolve.

A coating of the heater nano dye solution can be applied to a surface. In some instances, the heater nano dye solution is applied by an air gun. After application to a surface, the heater nano dye layer is stabilized (i.e., cured) by heating the heater nano dye to drive off the solvents and facilitate cross-linking of the polymethylphenylsiloxane. In some embodiments, the heater nano dye solution is cured at a temperature above 350° F., or above 390° F., or above 400° F., or above 500° F., or above 600° F. or above 700° F. or above 800° F. or above 900° F. while the heater nano dye solution can also be cured at a temperature below 1500° F., or below 1400° F., or below 1300° F. In some embodiments, the heater nano dye solution is cured at a temperature of approximately 1100° F. In some embodiments, the elevated temperatures can be maintained for at least 10 minutes, or at least 20 minutes, or at least 30 minutes. In some embodiments, the elevated temperatures are maintained for less than 3 hours, or less than 2 hours, or less than 1 hour.

Once cured, the solid heater nano dye layer includes a continuous polymer layer that includes the solid particles disposed therein. For example, in some embodiments, the continuous polymer layer can is formed by cross-linking the polymethylphenylsiloxane. The solid particles disposed (e.g., embedded) in the continuous polymer layer include, but are not limited to nanographite, special colorants (e.g., pigments), carbon particles, boron particles, and aluminum particles.

The prepared Heater Nano Dye may sometimes show different reactions due to the poor quality of the materials used in the mixture or due to the changes in the order and times of the mixture. The finished product that is realized with such kind of a Heater Nano Dye may crack when reaches to certain temperature or following a certain period of operation and may result with problems at temperature level. As a precaution against all these issues: the test rods are coated with the prepared heater nano dye with a pistol (airbrush) and evaluated at various resistance (ohm) values.

The obtained test rods are then tested for a certain period by means of using various voltages and applying voltage pulses at high and low temperatures. In case no problem (e.g., cracking, delamination, etc.) is observed in the Heater Nano Dye, then the sample passed from the quality control becomes ready for to be used in the production of the finished product. In case of any problem (e.g., cracking, delamination, etc.) in the test rods of the Heater Nano Dye, then the finished product manufactured with that sample is destroyed completely.

### Application Method

The Heater Nano Dye is applied on the surface of substructure that are desired to be heated. Examples of substructures that can be heated using the heater nano dye include, but are not limited to glass, wood, textile, stone, ceramic, iron and steel types, stainless steel and its types, copper, gold, silver, aluminum and other metal alloys. The surface of the substructure is heated by applying a voltage drop across the Heater Nano Dye.

Such composites can be formed with different construction and different structures in all kinds of heating systems and with the known technology. Although the general purpose is heating, they can operate at lower energies with the aid of the shown differences in all aspects and the minimum losses in the heat transfer.

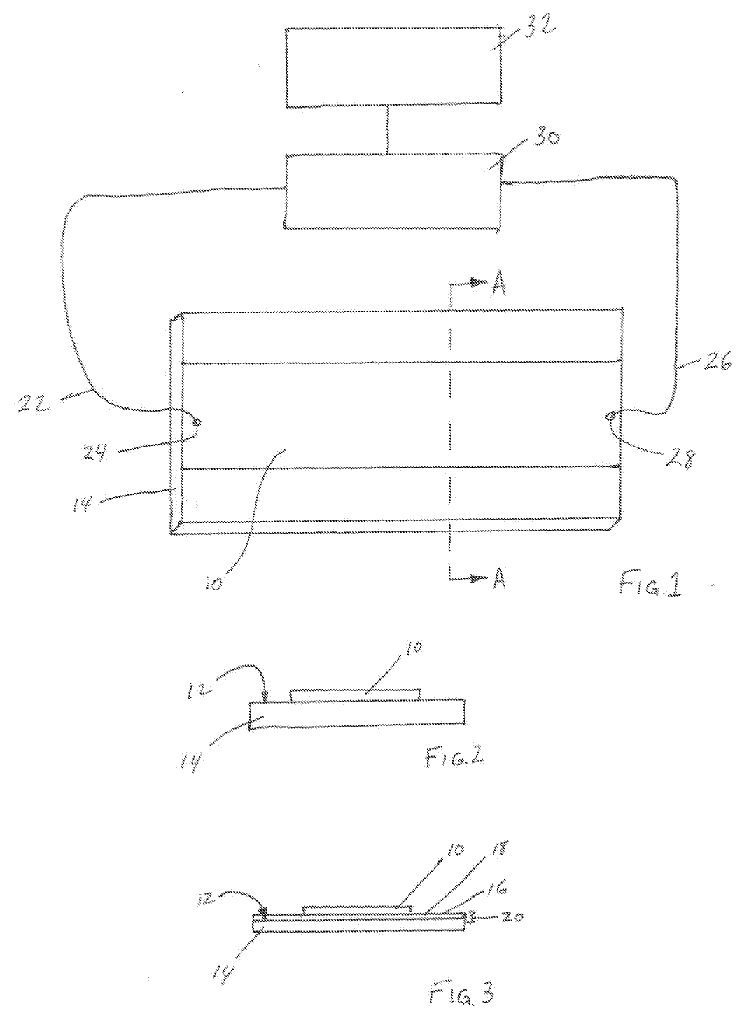

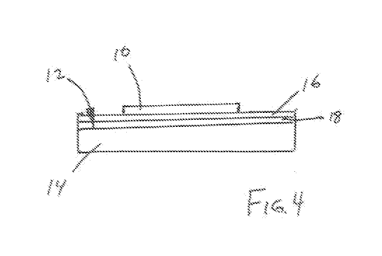

As shown in FIG. 1-3, the solid nano heater dye layer 10 can be applied over the surface 12 of substrate 14. In some embodiments, as shown in FIG. 3, a dielectric layer 16 can be applied over the surface 12 and the nano heater dye layer 10 can be applied over the dielectric layer 16. For example, an intermediate dielectric layer 16 may be particularly helpful where the substrate is conductive.

In some embodiments, a thermally insulating layer 18 can be applied over the substrate surface 12 and the solid nano heater dye layer 10 can be applied over the thermally insulating layer 18. In some embodiments, as shown in FIG. 4, the thermally insulating layer 18 can be between the nano heater dye layer 10 and the surface 12, and either above or below a dielectric layer 16. For example, an intermediate thermally insulating layer 18 can be helpful where the substrate is flammable or can otherwise be damaged by heat. In some instances, as shown in FIG. 3, a single intermediate layer 20 can have both dielectric and thermally insulating properties.

As shown in FIG. 1, a first electrode 22 can be electrically coupled to the nano heater dye layer at a first position 24, while a second electrode 26 can be electrically coupled to the nano heater dye layer at a second position 28, spaced apart from the first position 24. In some embodiments, the first and second electrodes 22, 26 can be coupled to a power system 30. In some embodiments, the power system 30 can be a power source adapted for applying a voltage drop across the nano heater dye layer 10. In some embodiments, the distance between the first position 24 and the second position 28 can be at least 3 inches, or at least 6 inches, or at least 12 inches. In some embodiments, the distance between the first position and the second position can be at least 90% of the length (i.e., the major axis) of the substrate, or at least 95% of the length of the substrate.

In some embodiments, the power system 30 includes a power source comprising a direct current power source. In some embodiments, the power system 30 comprises an alternating current power source. Such embodiments can be particularly adapted for resistive heating.

In some embodiments, the heater nano dye layer 10 can be used to generate electrical energy by absorbing thermal energy or electromagnetic radiation generated by the sun. In some embodiments, the power system 30 comprises an energy storage device adapted for storing electrical energy generated by absorption of thermal or electromagnetic energy by the heater nano dye layer 10. In some embodiments, the energy storage device is selected from the group consisting of a battery and a capacitor. In some embodiments, the power system 30 is in electrical communication with an electronic device 32 with an energy requirement and electrical energy generated by the heater nano dye layer 10 is supplied to the electronic device 32. As used herein, an electronic device 32 with an energy requirement is intended to refer to any device that requires electricity to operate or that is capable of storing energy.

The solid nano heater dye layer 10 can have a thickness range adapted to provide a desired resistance and/or heating level. For example, in some embodiments, the solid nano heater dye layer 10 can be at least 0.01 mm, or at least 0.05 mm, or at least 0.1 mm, or at least 0.2 mm. In some embodiments, the solid nano heater dye layer 10 can be 5 cm or less, or 2 cm or less, or 1 cm or less, or 5 mm or less of 2 mm or less.

In some embodiments, the Heater Nano Dye can be applied to the substrate surface with an airbrush (pistol), while the heater nano dye can also be applied with simple brushes, or other coating techniques as well.

The method of producing a substrate including a heater nano dye layer can include coating the surface with the heater nano dye and heating the heater nano dye until the cured heater nano dye layer is produced. The solvents are driven off in the form of smoke at the end of the reactions of the chemicals.

Following this process, as described above, the heating element is tested at certain period of time at certain voltages for the purpose of quality control and then becomes ready for use.

The heater nano dye can be applied as a liquid material, which facilitates ease of application to a wide variety of substrate topographies. The Heater Nano Dye appears like a dye (i.e., painted layer) on the dyed surface. Once applied and cured, the heater nano dye becomes a solid layer on the surface. The solid layer is durable and adapted for an extended useful lifetime.

In some embodiments, the power supply can provide alternating current, while the power supply can provide direct current in some embodiments. In some embodiments, the power source can apply an alternating current superimposed over a direct current (i.e., oscillation at a voltage other than 0 V. When the system is operated with direct current, the thermal efficiency equals the efficiency when operated with alternating current. It has no loss of efficiency.

The heater nano dye has been designed to work at any voltage. However, in some embodiments, the voltage operating range applied by the power source can range from 3 volts to 1,000 volts. It has the capacity to operate at higher voltages in case of necessity.

In some embodiments, the solid heater nano dye layer can be particularly adapted to absorb solar radiation or other sources of thermal energy, such as a hot liquid (e.g., water) or hot gas (e.g., steam). For example, in some embodiments, the absorption of the cured layer of heater nano dye can be at least 60% for solar radiation. In some embodiments, the cured heater nano dye can have an absorption of at least 70%, or at least 75%, or at least 80%, or at least 85%, or at least 90%.

In some embodiments, the solid heater nano dye layer can be adapted to have a high thermal conductivity. For example, in some embodiments, the solid heater nano dye layer can have a thermal conductivity of at least 10 W/m K, or at least 50 W/m K, or at least 100 W/m K, or at least 150 W/m K.

### EXAMPLES

### Example 1

In a first example, the heater nano dye can include nano graphite, polymethylphenysiloxane, butylene glycol, organic solvent (xylene, toluene, acetone), butyl acetate, and special colorant (e.g., pigments). The first liquid component can be formed by mixing butyl acetate, butylene glycol, and an organic solvent (e.g., toluene and/or acetone). The second liquid component can be formed by mixing polymethylphenylsiloxane, and organic solvent (e.g., xylene and/or toluene). The solids (e.g., nano graphite and special colorant) can then be mixed with the first and second liquid components and allowed to stand and/or are mixed for 75 minutes. This combination can then be mixed to form a uniform mixture and then applied to a surface using an air gun. The amounts of each ingredient can fall within the ranges set forth in Table 1.

### Example 2

In a second example, the heater nano dye can include nano graphite, polymethylphenysiloxane, butylene glycol, organic solvent (xylene, toluene, acetone), butyl acetate, carbon, and special colorant (e.g., pigments). The solids—nano graphite, carbon and special colorant—can be mixed together. The first liquid component can be formed by mixing butyl acetate, butylene glycol, and an organic solvent (e.g., toluene and/or acetone). The second liquid component can be formed by mixing polymethylphenylsiloxane, and organic solvent (e.g., xylene and/or toluene). The solids (e.g., nano graphite, carbon, and special colorant) can then be mixed with the first and second liquid components and allowed to stand and/or are mixed for 75 minutes. This combination can then be mixed to form a uniform mixture and then applied to a surface using an air gun. The amounts of each ingredient can fall within the ranges set forth in Table 1.

### Example 3

In a third example, the heater nano dye can include nano graphite, polymethylphenysiloxane, butylene glycol, organic solvent (xylene, toluene, acetone), butyl acetate, carbon, boron, and special colorant (e.g., pigments). The solids—nano graphite, carbon, boron, and special colorant—can be mixed together. The first liquid component can be formed by mixing butyl acetate, butylene glycol, and an organic solvent (e.g., toluene and/or acetone). The second liquid component can be formed by mixing polymethylphenylsiloxane, and organic solvent (e.g., xylene and/or toluene). The solids (e.g., nano graphite, carbon, boron, and special colorant) can then be mixed with the first and second liquid components and allowed to stand for 75 minutes. The liquid heater nano dye can be mixed to produce a uniform mixture and then applied to a surface (e.g., glass, ceramics, stone, wood, metal, etc.) using an air gun. If the heater nano dye is to be applied to a metal, a layer of dielectric material should be disposed between the metal surface and the solid heater nano dye layer. The liquid coating can then be cured be exposure to a temperature of 600° C. (1112° F.) for 1 to 3 hours. The amounts of each ingredient can fall within the ranges set forth in Table 1.

### Example 4

In a fourth example, the heater nano dye can include nano graphite, polymethylphenysiloxane, butylene glycol, organic solvent (toluene, acetone), butyl acetate, aluminum, and special colorant (e.g., pigments). The solids—nano graphite, aluminum, and special colorant—can be mixed together. The first liquid component can be formed by mixing butyl acetate, butylene glycol, and an organic solvent (e.g., toluene and/or acetone). The second liquid component can be formed by mixing polymethylphenylsiloxane, and organic solvent (e.g., toluene). The solids (e.g., nano graphite, aluminum, and special colorant) can then be mixed with the first and second liquid components and allowed to stand for 75 minutes. The liquid heater nano dye can be mixed to produce a uniform mixture and then applied to a surface (e.g., glass, ceramics, stone, wood, metal, etc.) using an air gun. If the heater nano dye is to be applied to a metal, a layer of dielectric material should be disposed between the metal surface and the solid heater nano dye layer. The liquid coating can then be cured be exposure to a temperature of 600° C. (1112° F.) for 1 to 3 hours. The amounts of each ingredient can fall within the ranges set forth in Table 1.

The foregoing is provided for purposes of illustrating, explaining, and describing embodiments of this invention. Modifications and adaptations to these embodiments will be apparent to those skilled in the art and may be made without departing from the scope or spirit of this invention.

1. An electrical system, comprising:
a substrate having a surface,
a solid heater nano dye layer disposed over the surface,
a power system having a positive terminal in electrical communication with a first position on the heater nano dye layer, and a negative terminal in electrical communication with a second position on the heater nano dye layer, wherein the heater nano dye layer comprises nanographite particles disposed within a continuous material.

2. The electrical system of claim 1, wherein the continuous material comprises a cross-linked polymer material.

3. The electrical system of claim 2, wherein the cross-linked polymer material comprises a cross-linked polymethylphenylsiloxane.

4. The electrical system of claim 1, wherein the power system comprises a power source comprising a direct current power source.

5. The electrical system of claim 1, wherein the power system comprises a power source comprising an alternating current power source.

6. The electrical system of claim 1, wherein the power system comprises an energy storage device adapted for storing electrical energy generated by the heater nano dye layer.

7. The electrical system of claim 1, wherein the energy storage device is selected from the group consisting of a battery and a capacitor.

8. The electrical system of claim 1, wherein the power system is in electrical communication with an electronic device with an energy requirement and electrical energy generated by the heater nano dye layer is supplied to the electronic device.

9. A heater nano dye comprising nano graphite, polymetylphenylsiloxane, organic solvent, alkylene glycol, and alkyl acetate.

10. The heater nano dye of claim 9, wherein the organic solvent comprises at least one solvent selected from the group consisting of xylene, toluene, and acetone.

11. The heater nano dye of claim 9, further comprise at least one solid component selected from the group consisting of carbon, aluminum, boron, and pigment.

12. A composite material formed by applying a coating of heater nano dye of claim 9 to a substrate, and curing the coating to form a solid heater nano dye layer.

13. The composite material of claim 12, wherein the coating is cured by heating the coating to a temperature above 200° F.

14. The composite material of claim 12, wherein the absorption of the cured layer of heater nano dye for solar radiation is at least 70%.

15. The composite material of claim 12, further comprising a dielectric layer disposed between the substrate and the heater nano dye.

16. A method of heating a surface, comprising:
providing a substrate surface with a solid heater nano dye layer of claim 12 disposed over the substrate surface; and
applying a voltage difference across the substrate surface.

17. A method of capturing thermal energy, comprising:
providing a substrate surface with a solid heater nano dye layer of claim 12 disposed over the substrate surface;
exposing the solid heater nano dye layer to a thermal energy source; and
placing the solid heater nano dye layer in electrical communication with an electronic device, wherein said solid heater nano dye layer generates electricity, which is provided to the electronic device.

18. The method according to claim 17, wherein the electronic device is an electronic storage device, and at least part of the electricity generated by the heater nano dye is stored by the electronic storage device.

19. The method according to claim 17, wherein the electronic device is an electronic device with an energy requirement, and at least part of the electricity generated by the heater nano dye is used to satisfy the energy requirement of the electronic device.
